(19) United States
(12) Patent Application Publication
(10) Pub. No.: US 2008/0053367 A1
(43) Pub. Date: Mar. 6, 2008

(54) METHOD AND APPARATUS FOR MANUFACTURING A TUBE

(75) Inventors: Albrecht SEIDL, Niedernberg (DE); Ingo SCHWIRTLICH, Miltenberg (DE)

Correspondence Address: DENNISON, SCHULTZ & MACDONALD, 1727 KING STREET, SUITE 105, ALEXANDRIA, VA, 22314, US

(73) Assignee: SCHOTT SOLAR GMBH, Alzenau (DE)

(21) Appl. No.: 11/839,706

(22) Filed: Aug. 16, 2007

(30) Foreign Application Priority Data
Sep. 4, 2006 (DE) 10 2006 041 736.4

(51) Int. Cl. C30B 15/20

(52) U.S. Cl. 117/16; 117/210; 117/25

(57) ABSTRACT

A method as well as an apparatus for manufacturing a tube according to the EFG-method. To manufacture tubes with a desired even wall thickness, it is proposed to draw the tube from a melt whose temperature can be controllably adjusted section by section.

### BACKGROUND OF THE INVENTION

The invention concerns a method for manufacturing a crystalline tube from a material such as silicon by drawing the tube from a melt created from the melting down of the material introduced to a crucible by means of a heater, where the melt penetrates a capillary slot molding the geometry of the tube and projects beyond this slot with a meniscus with a height h, which overflows into a seed crystal corresponding to the geometry of the tube or a lower peripheral area of a drawn section of the tube being manufactured. The invention also concerns an apparatus for drawing a tube out of a melt comprising a crucible with a capillary slot penetrated by the melt and molding the geometry of the tube, where the capillary slot is penetrated by the melt with a meniscus of a height h, and at least a heater associated with the crucible as well as a drawing device drawing the tube.

A corresponding method is also known as the EFG (edge-defined-film-fed-growth) method, with which polygonal, in particular octagonal tubes are drawn from a melt such as a silicon melt. Edge distances are typically 125 mm. Discs with edges measuring 100×100 mm or greater are cut out of the corresponding sides with a laser.

Apparatuses with which the EFG-method is performed have long been known and are comprehensively described. In this respect, reference is made to EP-B-0 369 574 or U.S. Pat. No. 6,562,132 as well as the literature cited in these documents. In this context, U.S. Pat. No. 6,562,132 governs the feeding of silicon particles to be melted and the electromagnetic field of induction coils for the heating of the melt.

DE-T-691 24 441 discloses a system for regulating an apparatus for crystal growing. In order to draw tubes with uniform wall thickness, it is proposed to use the actual weight of the growing crystalline body as a variable to feed the required amount of material into the melt.

U.S. Pat. No. 4,544,528 describes a device for drawing tubes according to the EFG-method. The device is distinguished through the presence of heat shields at the area of the transition between the melt and the solidified tube. Internal and external after-heaters are installed in the area of the solidified tube.

DE-A-23-25 104 concerns crystal-drawing methods for tubes and fibers. To keep the outer diameter of the tube within the prescribed limits, the height of the meniscus is measured, while temperature is regulated as a function of this height.

To grow monocrystals, RU-C-2 222 646 and RU-C-2 230 839 propose using a crucible containing a melt, where arranged in the crucible is a mold with canals that are penetrated by the melt. The canals terminate in the upper area of the mold at a seed crystal. For the melting process, a heating device is provided that consists of U-shaped plates bent to fit the shape of the crucible. The plates are arranged in sections to create a radially running isothermal state.

The drawing of tubes according to the EFG-method is described in “A 3D Dynamic Stress Module for the Growth of Hollow Silicon Polygons”, NL.Z.: BEHNKEN, H.; SEIDL, A.; FRANKE: Journal of Crystal Growth, 2005, Vol. 275, Page e375-e380.

### SUMMARY OF THE INVENTION

The goal of the present invention is to further develop a method and an apparatus of the type initially named so that tubes can be manufactured that feature a desired uniform wall thickness, i.e. exhibit a narrow thickness distribution. In particular, the average amount of material used to create the tube should be minimized. In particular during the manufacture of wafers made of silicon, thicknesses should be attainable that allow a high filling degree and thus a high degree of effectiveness for a solar power cell.

According to the invention, the goal is essentially attained through a method of the type initially named in such a way that the temperatures in adjacent areas of the melt are adjusted through regulation independently of one another.

In particular, it is provided that the temperature of the melt in the individual areas is regulated as a function of the height h of the meniscus of the melt flowing out of the respective area into the capillary slot and/or as a function of the wall thickness t of the tube section drawn from the area.

Deviating from the state of the art, a regulating process is proposed on the basis of which reproducible tubes with a narrow thickness distribution can be manufactured with wall thickness being minimized so that the average amount of silicon used can be minimized particularly in the manufacture of silicon rods for the production of wafers. The tube is then drawn from a melt in which the temperature is controllably adjusted by section and segment.

According to the invention, the temperature of the melt can be regulated so that in the meniscus, namely in the transition between the melt and the solidified tube section, a temperature prevails that corresponds to the melting point of the material. In the case of silicon being used as the material in particular, the temperature is equal to 1,412° C.±2° C., where the temperature is held constant within 0.1° C. to 2° C.

So that it is not necessary to directly measure the temperature in the meniscus, the parameters of height h of the meniscus or thickness t of the tube in the respective area or above can be used as variables to set the temperatures in the area as a function of the measured values. At the same time, the drawing speed can be modified accordingly, while in principle both the drawing speed and the temperature should be regulated.

Tube thickness is preferably measured at the peripheral area of the drawing device.

Temperatures in the individual areas are independently regulated by having a separate heating element, preferably a resistance heating element, assigned to each area, where the heating elements are preferably connected to one another in a star circuit.

However, it is also possible to have a single heating element assigned to all areas. In such case, the heating element used is an induction heating element, that is, the crucible is surrounded by an induction coil. However, to allow the temperature to be adjusted in the individual areas corresponding to the regulation to be undertaken, the magnetic field is individually varied in each area. For this purpose, ferrite elements that influence the magnetic field are provided. Each ferrite element assigned to an area can be radially displaced, for example, by means of a motor. It is thus possible through simple measures to regulate the temperature of the melt in such a way that the required constant temperature prevails in the meniscus.

It is envisioned that the drawing speed should be adjusted to a value between 7 mm/min to 24 mm/min with a tolerance of 1 mm/min, where the preferred drawing speed is between 12 mm/min and 15 mm/min.

If the tube is of polygonal geometry, then an area is assigned to each side of the polygon, that is, the temperature of each side is regulated independently. Thus in an octagon, eight heating elements or eight ferrite elements independently adjustable from one another are provided when an induction heating element is used. In a dodecagon, accordingly, twelve heating elements or ferrite elements are present to facilitate the regulation of temperature.

If a resistance heating element is used, it should preferably be made of graphite. Metallic resistance heating elements with which the required temperatures for adjusting the melt temperatures can be generated are also an option.

Because of construction factors, the temperature of the melt is frequently not directly measured. Instead, the temperature of the wall of the molten bath is ascertained, for example, with a pyrometer. However, it is also possible to directly ascertain the melt temperature by means of a thermocouple, for example.

An optical sensor is used to measure the height h of the meniscus, that is, the transition between the solid and liquid phase. In particular, a CCD-camera with image processing is provided. For this purpose, viewing windows can be present in the shell of the molten bath to allow the height h of the meniscus to be ascertained in each area.

The wall thickness of the tube section drawn from the area can be measured interferometrically, for example, with an IR-interferometer. The respective measuring devices for measuring wall thickness and the height of the meniscus are connected to a regulator, via which the heating of the individual areas is then regulated. The drawing speed can also be prescribed by the regulator.

Furthermore, the material to be melted down can be fed into the crucible in such a way that the amount supplied to each area corresponds to the amount which was drawn from the melt. For this purpose, the tube and the material feed are each connected to a load cell to facilitate the required regulation.

Based on the tenet of the invention, it is possible, in contrast to the previously known EFG-method for manufacturing tubes, to commercially manufacture tubes with a circumference of more than 1 m, in particular 1.50 m or greater and a length of more than 5.50 m, preferably greater than 6 m, whereby wall thickness exhibits a narrow thickness distribution. In particular, it is possible to manufacture tubes with wall thicknesses between 100 μm and 300 μm with a tolerance between 8 to 12%. If the drawn tube is made of silicon, silicon wafers of desired sizes, particularly with edges up to 156 mm (6 inches) in length, wall thicknesses below 350 μm, in particular below 290 μm, can thus be manufactured so that there result a high filling factor, a high short circuit current thickness and a high open-circuit voltage of a polycrystalline silicon solar cell manufactured from the wafer, values which at least on a commercial scale are not possible to achieve according to the state of the art at a degree of reproducibility made possible through the invention.

The method of the type initially named is distinguished particularly by the fact that the temperature of the melt—preferably in adjacent areas independent of one another—is regulated in such a way that the temperature of the meniscus is kept at a constant or nearly constant value over the entire length of the slot and/or the temperatures of the adjacent areas of the crucible are regulated independently from one another as a function of the height h of the meniscus of the melt flowing out of the area into the capillary slot and/or as a function of the wall thickness t of the tube section drawn from the area and/or the drawing speed of the tube section drawn from the melt is regulated as a function of the height h of the meniscus and/or the wall thickness t of the tube section.

An arrangement of the type initially named is distinguished by the fact that the temperatures of the individual areas of the crucible or melt, in particular those bordering one another, can be individually regulated by means of one or more heaters. In particular, it is provided that a resistance heating element is assigned to each area, where the resistance heating elements can be connected to one another in a star circuit.

However, it is also possible to assign an induction heating element—such as coil—to all areas, where a ferrite element influencing the magnetic filed is assigned to each area, which can be adjusted independently of one another. In particular, each ferrite element can be adjusted by means of a motor.

In a further development it is envisioned that assigned to each area is a first measuring device measuring the height h of the meniscus, where the device employed is a CCD camera with a connected image-processing unit.

The sensors for measuring wall thickness t should be arranged at a sufficient distance from the melt, preferably in the upper peripheral area of the drawing machine or its housing.

In an improvement, the invention provides that assigned to each area is a second measuring device measuring the wall thickness t of the tube section drawn from the area, where the measuring device is an interferometer such as an IR-interferometer.

The first and/or second measuring device and the heaters regulating the temperatures of the areas are connected via a control unit, which should also be connected to the drawing device.

A tube manufactured according to the inventive method is distinguished particularly by the fact that the tube features a circumference U, where U≧100 cm, in particular U≧150 cm, a length L, where L≧550 cm, in particular L≧600 cm, and a wall thickness t, where 100 μm≧t≧500 μm. The tube is preferably of dodecagonal geometry.

The preferred wall thicknesses of the tube lie between 250 μm and 350 μm at a thickness tolerance between 20% and 30% and between 100 μm and 240 μm at a thickness tolerance between 8% and 12%.

When resistance heating elements are used as the heaters regulating the temperature in the individual areas, it is envisioned in an improvement of the invention, that the arrangement is surrounded by a metal housing—an option not possible when an induction heater is used. The top of the metallic housing features an aperture corresponding to the geometry of the tube for the purpose of conducting the tube. The resistance heating elements are preferably made of graphite.

The sensors for measuring wall thickness are preferably located in the top area.

For measuring temperature, temperature sensors such as pyrometers or thermocouples are provided, whereby the pyrometer is used to measure the base wall of the crucible, in order to allow conclusions to be drawn on melting point temperature.

The crucible is of ring-shaped geometry, whereby the outer diameter is 5% to 15% greater than the longest diagonal of the tube.

The capillary slot is connected to the crucible, i.e. the melt present therein, via a plurality of small holes or slits. If the slot is of polygonal geometry, then each side of the polygon is associated with one of the areas, whose temperatures can be regulated independently.

For feeding the material to be melted down to the crucible, a feeding device leads through the base of the apparatus to then distribute the material evenly among the individual areas of the crucible via a reversing device.

Above the crucible, the tube drawn from the flux is surrounded by insulation elements to facilitate a systematic cooling-off.

### BRIEF DESCRIPTION OF THE DRAWINGS

Additional details, benefits and features of the invention are found not only in the claims or the features that can be derived from them individually and/or in combination, but also in the following description of the preferred embodiment illustrated in the drawing.

Shown are:

FIG. 1 A principal illustration of a first embodiment of an apparatus for drawing a tube out of a melt,

FIG. 2 A detail of the apparatus shown in FIG. 1,

FIG. 3 An equivalent circuit diagram,

FIG. 4 A principal illustration of a second embodiment of an apparatus for drawing a tube from a melt,

FIG. 5 A detail of the apparatus illustrated in FIG. 4 and

FIG. 6 A principal illustration for ascertaining variables.

### DESCRIPTION OF THE PREFERRED EMBODIMENTS

The figures, which in principle use the same reference numbers for the same elements, illustrate the configurations and their respective details with which the tubes are drawn according to the EFG-method. However, this invention is not limited to tubes of polygonal geometry. The tubes can also be of circular cross-section.

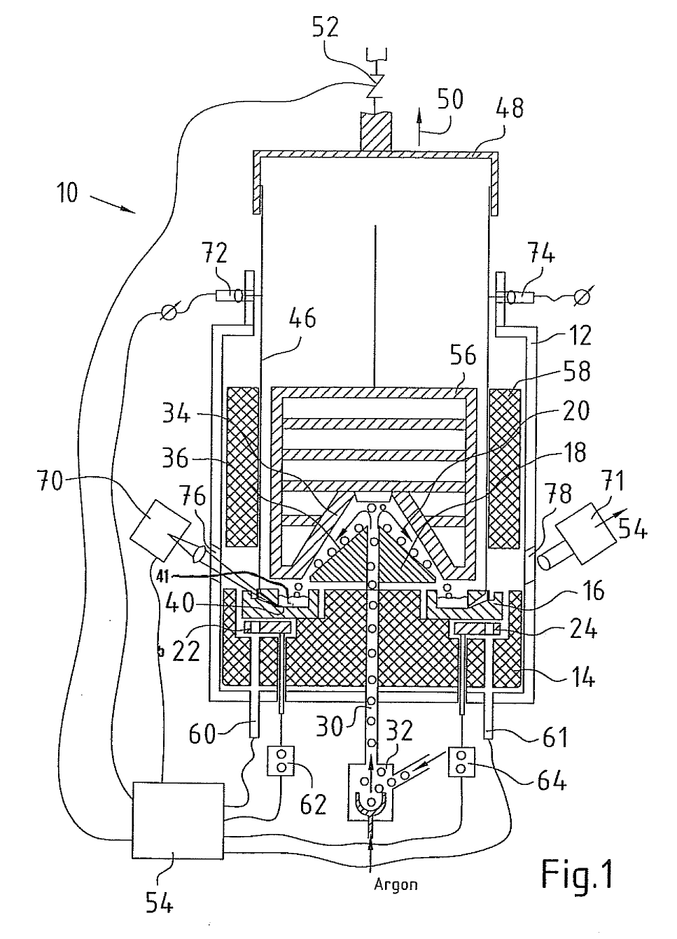

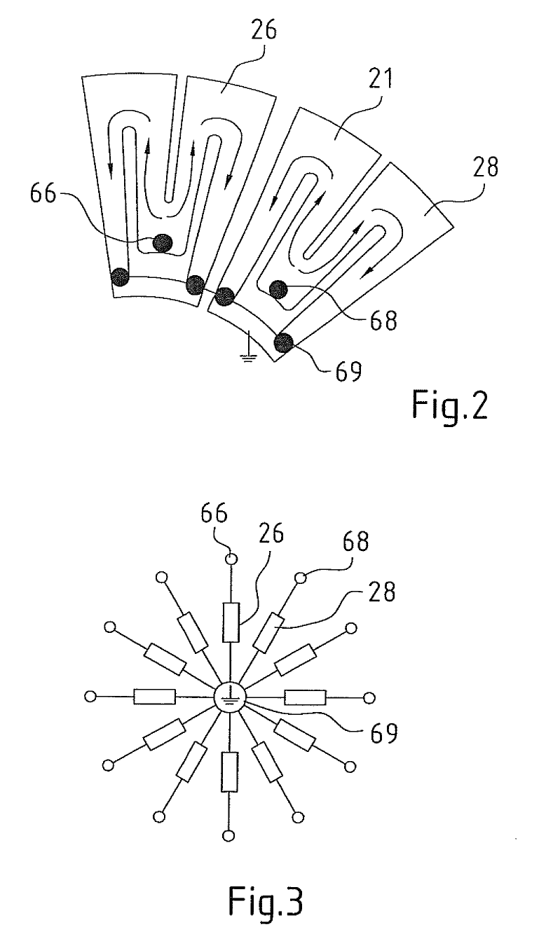

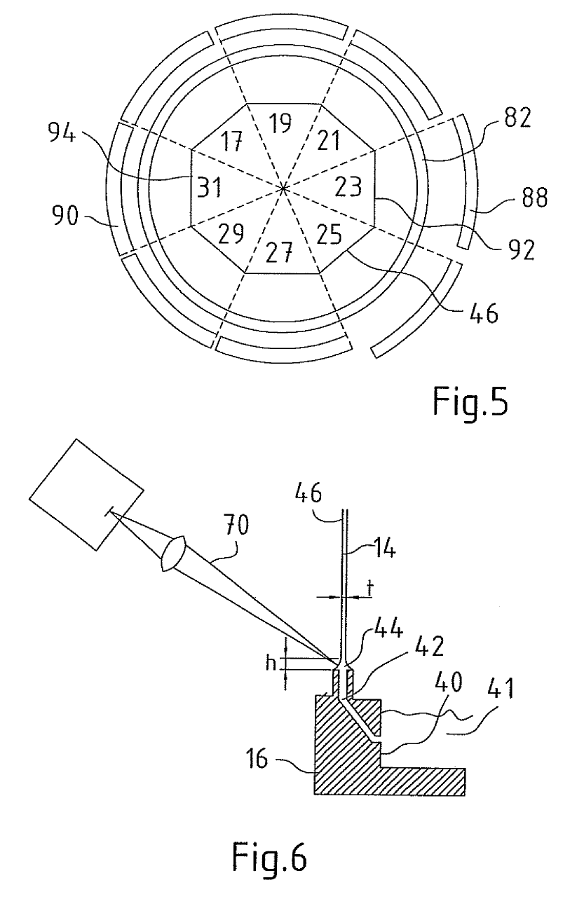

As FIG. 1 illustrates, the configuration 10 features a housing 12 that constitutes a receptacle, which accepts a base insulation 14, in which a ring-shaped crucible 16 is arranged. In the crucible 16 a material 20 supplied via feed device 18 is melted down. In the embodiments illustrated in FIG. 1 and FIG. 2 this is accomplished namely by means of resistance heating elements 22, 24, 26, 28, through which the adjacent areas of the crucible 16 can be heated independently. A corresponding breakdown is illustrated in FIG. 5 and labeled with the reference numbers 17, 19, 21, 23, 25, 27, 29, 31.

The material fed into the crucible 16, can be of spherical, polygonal or powder-formed geometry and is introduced via an opening 30 penetrating the base of the housing 12 and the base insulation 14 by means of a blowing device 32. A conical element 34 resembling an umbrella reverses the direction of movement, so that the material forming a granulate on the basis thereof is directed along the surface 36 of a conical element in the direction of the crucible 16, i.e. its ring-shaped intake 40. As a result, there is an equal distribution of the granulate across the entire circumference of the ring-shaped intake 40.

As FIG. 6 illustrates, running in the outer area of the crucible 16 is a slot 42 producing a capillary effect, which is connected to the silicon melt 41 via slits or holes so that the melt 41 flows into the slot 42 and, owing to the capillary effect, exits this on the top-side, i.e. on the upper edge, and forms a meniscus 44. When a tube 46 is drawn, apex of the meniscus 44 solidifies, so that the tube 46 or the solidified sections can be raised by means of a drawing device 48 in the direction of the arrow 50. For the purpose of precisely coordinating the amount of the granulate 20 fed to the crucible 60 with the amount of the drawn tube section, the drawing device 48 is connected to a load cell 52, the measurement values of which are fed to a control unit 54.

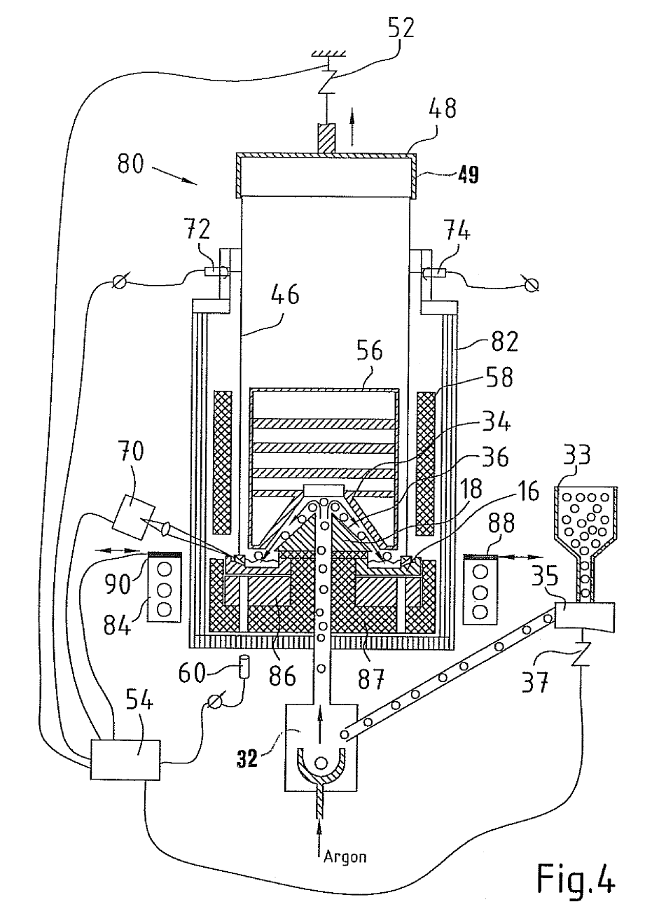

The material to be melted down is fed from a receiver 33 to the blowing device 32 via a dosing device 35 (FIG. 4). The dosing device 35 is connected to the control unit 54 via a load cell 37, so that precisely the amount of material to be melted, which is drawn from the melt, i.e. the capillary slot 42, is fed to the crucible 16 via the blowing device 32. This amount is ascertained by means of the load cell 52.

The drawing device 48 comprises a seed crystal holder 49, which at the start of the drawing process is of the same geometry of the seed crystal corresponding to the tube to be drawn, where the seed crystal comes into contact with the meniscus 44.

Furthermore, above the crucible the tube 46 is surrounded by an insulation 58 and radiation shields 56 to allow the controlled cooling of the tube 46.

In order to regulate the drawing process, whereby it should be ensured, that the tube 46 features a reproducible wall thickness at a narrow thickness distribution, whereby the wall thickness is simultaneously adjusted in such a way, that the amount of the material such as silicon is minimized, the invention provides, that in the crucible 16 the temperature of the melt is individually regulated in the adjacent areas 17, 19, 21, 23, 25, 27, 29, 31, and whereby in a tube of polygonal geometry each area corresponds to a side of the polygon. If, on the other hand, the tube has a circular cross-section, the areas individually temperature regulated are adapted to a width of the tube in which plates are cut from the tube to be used, for example, as wafers for manufacturing solar cells.

To facilitate reproducibly manufacturing wall thickness with a narrow thickness distribution, the melting point temperature of the material 20, 1,412° C. in the case of silicon, must prevail in the meniscus 44, namely in the transition between solid and liquid phase, and remain constant, fluctuating less than 2° C., in particular, between 0.1° C. and 2° C.

To facilitate measurement in a simple manner, the temperature of the meniscus 44 is not ascertained directly. Instead, in the variant illustrated in FIG. 1, the temperature of the base of the crucible 16 is measured by means of pyrometers 60, 61, which penetrate the resistance heating units 22, 24, 26, 28. Temperature regulation is provided by means of a control unit 54, which is connected to the resistance heating units 22, 24, 26, 28 via the regulatable supply terminals 62, 64, 66, 68. The measured heights h of the meniscus 44 in the individual areas 17, 19, 21, 23, 25, 27, 29, 31 are fed to the control unit 54 to facilitate regulating the temperature in the areas 17, 19, 21, 23, 25, 27, 29, 31 as a function of these heights. The heights h are measured with optical sensors 70, 71. In particular, a CCD-camera with connected image processing is used as sensor. If the heights of the meniscus 44 change, the temperature of the heating element 22, 24, 26, 28 and thereby the melt 41 are changed to restore the required height h of the meniscus 44, where the wall thickness t of the tube 46 is a direct function of height (h=f(t)).

According to the invention, the melt temperature and thereby the temperature of the meniscus 44 are thus regulated in the solid-liquid phase transition based on the ascertained height h of the meniscus 44.

As a supplemental or alternative option, it is also possible to regulate by measuring the thickness t of the tube 46. For this purpose, interferometers 72, 74 are provided on the upper edge of the housing 12 as FIG. 1 illustrates, where an interferometer 72, 74 is respectively assigned to an area 17, 19, 21, 23, 25, 27, 29, 31, just as the sensors 70, 71 for measuring the height h of the meniscus 44. If, for example, the tube 46 features a dodecagonal geometry, then each of the 12 sides is respectively assigned to an optical sensor 70 or 71 and an interferometer 72 or 74. As FIG. 5 illustrates, in an octagonal tube 46, eight areas 17, 19, 21, 23, 25, 27, 29, 31 can be regulated, each of which is assigned to a surface 92, 94 of the tube 46.

FIG. 2 illustrates a section of the resistance heating element, which is assigned to the crucible 16. Thus in FIG. 2 two heating elements 26, 28 are illustrated, where each heating element 26, 28 independently regulates the temperature in an area of the crucible. In principle, one heating element 26, 28 is assigned to one side of the tube 46, provided that the tube is of polygonal geometry. If a dodecagonal tube is drawn, then 12 heating elements are provided, which are connected in a star circuit as illustrated in the equivalent circuit diagram in FIG. 3. The outer connections 66, 68 are then connected to the control unit 54, while the inner connections 69 are connected to one another and then grounded.

In the embodiment illustrated in FIG. 1, the housing 12 is made of steel and is water-cooled. To allow the meniscus 44 to be optically captured, windows 76, 78 are left in the housing 12 corresponding to the areas 17, 19, 21, 23, 25, 27, 29, 31 which are to be temperature-regulated. The variant in FIG. 4 differs from that in FIG. 1 in that the areas 17, 19, 21, 23, 25, 27, 29, 31 to be independently temperature-regulated by regulation are not heated by resistance heating elements, but rather through an induction heater. For this purpose, the arrangement 80 features a housing 82 or receptacles made of double-plated glass and surrounded by an induction coil 84. To heat the crucible 16 and thus the melt 41 present therein, a susceptor 86 generating the heat is arranged below the ring-shaped crucible. The susceptor 86 is made of graphite. In this example the susceptor 86 is surrounded by an insulation 87 in the usual way, which extends along the base and side wall of the housing 82 made of a glass double jacket. The arrangement 80 otherwise features the same basic construction as illustrated in FIG. 1.

To allow the areas 17, 19, 21, 23, 25, 27, 29, 31 of the melt 41 to be individually temperature-regulated to a desired extent corresponding to the tent of the invention in a regulating process, there is assigned to each area 17, 19, 21, 23, 25, 27, 29, 31 a displaceable element 88, 90 made of a ferritic material, via which the magnetic field of the induction coil 84 is influenced so that the desired heating of the melt 41 occurs in such a way, that the meniscus 44 exiting the slot 42 exhibits the desired temperature, 1,412° C. for silicon, at a high degree of stability.

The temperature of the melt 41 is indirectly measured according to the models in conjunction with FIG. 1, namely by ascertaining the temperature of the crucible 16. This is performed using a pyrometer 60, where a pyrometer 60 is assigned to each area 17, 19, 21, 23, 25, 27, 29, 31 which is to be independently temperature-regulated. The height h of the meniscus 44 and the thickness 5 of the wall thickness of the tube 46 are both measured in the manner previously described.

From FIG. 5 it should be clear, that assigned to the induction coil 84 corresponding to the areas 17, 19, 21, 23, 25, 27, 29, 31 to be individually temperature-regulated are adjustable ferrite elements 88, 90, where the number of the ferrite elements 88, 90 corresponds to the number of sides 92, 94 of the tube 46. The ferrite elements 88, 90 can be adjusted, for example, radially in relation to the tube 46 by means of servo-motors.

1. Method for manufacturing a crystalline tube (46) from a material such as silicon by drawing the tube from a melt (41) created from the melting down of the material introduced to a crucible (16) by means of a heater (22, 24, 26, 28, 84, 86), wherein the melt penetrates a capillary slot (42) molding the geometry of the tube and projects beyond this slot with a meniscus (44) with a height h, which overflows into a seed crystal corresponding to the geometry of the tube or a lower peripheral area of a drawn section of the tube being manufactured, characterized in that the temperatures of the individual areas (17, 19, 21, 23, 25, 27, 29, 31) of the melt (41) can be adjusted independently from one another through a regulator.

2. Method according to claim 1, wherein the temperature of the melt (41) in the adjacent areas (17, 19, 21, 23, 25, 27, 29, 31) can be regulated as a function of the height h of the meniscus (44) of the melt flowing out of the area into the capillary slot (42) and/or as a function of the wall thickness of the tube section being drawn out of the area.

3. Method as claimed in claim 1, wherein the temperature of the individual areas (17, 19, 21, 23, 25, 27, 29, 31) of the melt (41) is regulated in such a way that the temperature of the meniscus is kept at a constant or nearly constant value over the entire length of the slot.

4. Method as claimed in claim 1, wherein the tube (46) is of polygonal geometry, and assigned to each side surface of the polygonal tube (46) is an area that is temperature-regulated independently of the other areas (17, 19, 21, 23, 25, 27, 29, 31).

5. Method according to claim 1, wherein the temperature of each area (17, 19, 21, 23, 25, 27, 29, 31) is regulated by a separate heating element, such as a resistance heating element (22, 24, 26, 28)

6. Method according to claim 1, wherein all areas are temperature-regulated by an induction heating element (84), whereby assigned to each area is a ferritic element (88, 90), which influences the magnetic field of the induction heating element and can be displaced independently from the other elements.

7. Method as claimed in claim 6, wherein the ferritic element (88, 90) is radially displaced in relation to the tube (46) by means of a controllable motor.

8. Method as claimed in claim 2, wherein the height h of the meniscus (44) is measured with an optical sensor (70, 71)

9. Method as claimed in claim 2, wherein the height h of the meniscus (44) is measured with a CCD-camera (70, 71) and a connected image-processing unit.

10. Method as claimed in claim 1, wherein the temperature of the melt (41) is directly or indirectly measured by means of a pyrometer (60, 61) or thermocouple.

11. Method as claimed in claim 2, wherein the wall thickness is measured by means of an interferometer (72, 74).

12. Method as claimed in claim 5, wherein the resistance heating elements (22, 24, 26, 28) assigned to the areas are connected in a star circuit.

13. Method for manufacturing a tube (46) from silicon as claimed in claim 1, wherein the temperature of the meniscus (44) is kept constant along the entire length of the capillary slot (42) within ≦2° at temperature T, where T=1,412° C.

14. Method as claimed in claim 1, wherein the tube (46) is drawn from the melt (41) at a drawing speed between 10 mm/min. and 24 mm/min. with a tolerance of 1 mm/min.

15. Method as claimed in claim 14, characterized in that the tube (46) is drawn from the melt (41) at a drawing speed between 10 mm/min. and 15 mm/min.

16. Method as claimed in claim 1, wherein the temperature of the melt (41) is regulated in such a way that the temperature of the meniscus (44) is kept at a constant or nearly constant value over the entire length of the slot (42) and/or the temperatures of the adjacent areas (17, 19, 21, 23, 25, 27, 29, 31) of the crucible (16) are regulated independently from one another as a function of the height h of the meniscus of the melt flowing out of the area into the capillary slot and/or as a function of the wall thickness t of the tube section drawn from the area and/or the drawing speed of the tube section drawn from the melt is regulated as a function of the height h of the meniscus and/or the wall thickness t of the tube section.

17. Apparatus (10, 80) for drawing a tube (46) out of a melt (41) comprising a crucible (16) with a capillary slot (42) penetrated by the melt and having a predetermined geometry of the tube, which capillary slot can be exceeded by the melt with a meniscus (44) with a height h, and at least a heater (22, 24, 26, 28, 84, 86) assigned to the crucible, as well as a drawing device (48) drawing the tube, thereby characterized by areas of the crucible (16) and/or the melt (41) bordering each other (17, 19, 21, 23, 25, 27, 29, 31) being temperature-controlled independent of each other by means of one heater or several heaters (22, 24, 26, 28, 84).

18. Apparatus as claimed in claim 17, wherein a resistance heating element (22, 24, 26, 28) is assigned to each area (17, 19, 21, 23, 25, 27, 29, 31).

19. Apparatus as claimed in claim 18, wherein the resistance heating elements (22, 24, 26, 28) are connected in a star circuit.

20. Apparatus as claimed in claim 18, wherein an induction heating element (84) is assigned to all areas (17, 19, 21, 23, 25, 27, 29, 31) and a ferritic element (88, 90) influencing the magnetic field of the induction heating element is assigned to each area, whereby the ferritic elements can be displaced independently of one another.

21. Apparatus as claimed in claim 20, wherein the ferritic element (88, 90) can be displaced radially in relation to the tube (46) by means of a motor.

22. Apparatus as claimed in claim 17, wherein a first measuring device (70, 71) measuring the height h of the meniscus (44) is assigned to each individually heatable area (17, 19, 21, 23, 25, 27, 29, 31).

23. Apparatus as claimed in claim 22, wherein the first measuring device (70, 71) is a CCD-camera with an image-processing unit.

24. Apparatus as claimed in claim 17, wherein a second measuring device (72, 74) measuring wall thickness t of the tube section drawn from the area is assigned to each individually heatable area (17, 19, 21, 23, 25, 27, 29, 31).

25. Apparatus as claimed in claim 24, wherein the second measuring device (72, 74) is an interferometer.

26. Apparatus as claimed in claim 17, wherein the first and/or second measuring device (70, 71, 72, 74) and the heater (84) or heaters (22, 24, 26, 28) capable of regulating the temperature of the areas (17, 19, 21, 23, 25, 27, 29, 31) are connected to a control unit (54).

27. Apparatus as claimed in claim 26, wherein the drawing device (48) is connected to the control unit (54).

28. Apparatus as claimed in claim 17, wherein the capillary slot (42) is of polygonal geometry and that each side of the polygon is assigned to one of the areas (17, 19, 21, 23, 25, 27, 29, 31).

29. Apparatus as claimed in claim 18, wherein the resistance heating element (22, 24, 26, 28) is made of graphite.

30. Apparatus as claimed in claim 17, wherein the base of the crucible (16) can be sensed by a pyrometer (60, 61).

31. Apparatus as claimed in claim 17, wherein the crucible (16) features an outer diameter that is 5 to 15% greater than the longest diagonal of the tube (46).

32. Apparatus as claimed in claim 17, wherein the capillary slot (42) is connected to the melt (41) via slits or holes.

33. Apparatus as claimed in claim 17, wherein the apparatus features a steel housing enveloping the crucible (16).

34. Apparatus as claimed in claim 17, wherein the housing (12) is water-cooled.

35. Tube (46), manufactured according to the method claimed in claim 1, wherein the tube (46) features a circumference U, where U≧100 cm, a length L, where L≧550 cm, and a wall thickness t, where 100 μm≧t≧500 μm.

36. Tube as claimed in claim 35, wherein the tube (46) features a circumference U, where U≧150 cm and/or a length L, where L≧600 cm

37. Tube as claimed in claim 35, wherein the tube (46) is of dodecagonal geometry.

38. Tube as claimed in claim 35, wherein the tube features a wall thickness t, where 100 μm≦t≦300 μm.
